(19) United States
(12) Patent Application Publication
(10) Pub. No.: US 2013/0134421 A1
(43) Pub. Date: May 30, 2013

(54) SEMICONDUCTOR CHIP HAVING PLURAL PENETRATING ELECTRODES THAT PENETRATE THERETHROUGH

(71) Applicant: Elpida Memory, Inc., Tokyo (JP)

(72) Inventors: Kazuya TAKAKURA, Tokyo (JP); Toru ISHIKAWA, Tokyo (JP)

(73) Assignee: Elpida Memory, Inc., Tokyo (JP)

(21) Appl. No.: 13/688,123

(22) Filed: Nov. 28, 2012

(30) Foreign Application Priority Data
Nov. 29, 2011 (JP) 2011-260091

(51) Int. Cl. H01L 23/48

(52) U.S. Cl. CPC H01L 23/481; H01L 22/32; H01L 22/14
USPC 257/48; 257/774; 438/18

(57) ABSTRACT

Disclosed herein is a semiconductor chip that includes: a semiconductor chip body including a semiconductor substrate and a circuit element layer provided on a main surface of the semiconductor substrate, the circuit element layer including a plurality of circuit elements; first to fourth penetrating electrodes penetrating the semiconductor chip body; a first conductive path electrically connected between the first penetrating electrode and the second penetrating electrode without being in contact with any one of the circuit elements; a second conductive path electrically connected between the first penetrating electrode and the third penetrating electrode without being in contact with any one of the circuit elements; and a third conductive path electrically connected between the second penetrating electrode and the fourth penetrating electrode without being in contact with any one of the circuit elements.

### BACKGROUND OF THE INVENTION

1. Field of the Invention

The present invention relates to a semiconductor chip having plural penetrating electrodes that penetrate therethrough, a method of measuring a resistance thereof.

2. Description of Related Art

Along with miniaturization of electronic devices, demands for higher integration degree and miniaturization of semiconductor devices to be mounted in the electronic devices have arisen. Under such circumstances, a system-in-package technology in which various mounting structures are proposed is now attracting attention. In this technology, a plurality of semiconductor chips each having a circuit element layer are mounted in high density to achieve a sophisticated system in a short period.

For example, a stacked-type semiconductor device in which a plurality of semiconductor chips are stacked in a three-dimensional manner is developed to achieve a miniaturization of the semiconductor device. In such a stacked-type semiconductor device, the stacked semiconductor chips are electrically connected through a penetrating electrode.

The penetrating electrode electrically connects a front surface electrode formed on a front surface of a circuit element layer on a main surface (front surface) of a semiconductor substrate to a rear surface electrode formed on a rear surface of the semiconductor substrate opposite to the main surface.

Japanese Patent Application Laid-Open No. 2009-181981 (Patent Document 1) discloses a semiconductor device or semiconductor chip in which a through hole exposing one of surfaces of an element surface electrode formed on a surface-protecting insulating film is formed in a semiconductor substrate, and then a through Si conductor covering an inner surface of the through hole is formed to a thickness that does not fill the through hole.

Patent Document 1 also discloses that a ring-shaped insulating film surrounding an outer wall of the through Si conductor is formed in the semiconductor substrate.

Japanese Patent Application Laid-Open No. 2009-260292 (Patent Document 2) discloses a semiconductor device manufacturing method including a step of forming in a semiconductor substrate at least three kinds of through holes having a large area, a middle area, and a small area of openings, respectively; forming a through Si conductor in at least the three kinds of through holes to thickness that do not fill the through holes; and measuring resistance values of the through Si conductors formed in the through-hole having the large area of the opening and the through-hole having the small area of the opening to determine states of connection of the through Si conductors.

However, the through Si conductors each formed to a thickness that does not fill the through hole) disclosed in Patent Documents 1 and 2 each have a cross-section area smaller than that of the through hole and are therefore disadvantageously increased in resistance.

In order to solve this problem, Japanese Patent Application Laid-Open No. 2010-272737 (Patent Document 3) discloses a technique in which the through Si conductor is formed so as to fill the through hole penetrating the semiconductor substrate.

In the technique disclosed in Patent Document 3, forming the through Si conductor so as to fill the through hole increases the cross-section area of the through Si conductor as compared to those of the penetrating electrodes disclosed in Patent Documents 1 and 2, allowing a reduction in the resistance value of the through Si conductor.

A four-terminal method is known as a method of accurately measuring a resistance value of a penetrating electrode (electrode penetrating a semiconductor substrate and a circuit element layer).

A principle of the four-terminal method is as follows. Two terminals are connected to a constant current source, and remaining two terminals are used for voltage measurement. Constant current is applied to an object to be measured, and the constant current flows through the object to be measured even when contact resistance is present. Voltage of the object to be measured is measured by the voltage measurement terminals that are not directly connected to the constant current source and thus little current flows through the voltage measurement terminals, so that a voltage drop is negligibly-small even if the contact resistance is present, thereby allowing measurement of a low resistance.

In the semiconductor device (semiconductor chip) described in Patent Document 3, a diameter of a Ni—Au sedimentary layer (rear surface bump electrode) functioning as an external connection terminal is almost equal to a diameter of the through hole.

Further, in a semiconductor device (semiconductor chip) exchanging a large number of signals with an external device through the penetrating electrode, a large number of the penetrating electrodes is required. It follows that the diameter (size) of each penetrating electrode is reduced, and along with the reduction in the diameter of each penetrating electrode, the diameter (size) of the rear surface bump electrode functioning as the external connection terminal is reduced.

The following problem arises when the miniaturization of the through hole is progressed as described above. That is, in measuring a resistance value of the penetrating electrode using the four-terminal method, two contact probes of a probe device (electric testing device) cannot be brought into contact with one rear surface bump electrode.

That is, the resistance of the miniaturized penetrating electrode cannot be measured by using the four-terminal method.

### SUMMARY

In one aspect of the present invention, there is provided a semiconductor chip that includes: a semiconductor chip body including a semiconductor substrate and a circuit element layer provided on a main surface of the semiconductor substrate, the circuit element layer including a plurality of circuit elements; first to fourth penetrating electrodes penetrating the semiconductor chip body; a first conductive path electrically connected between the first penetrating electrode and the second penetrating electrode without being in contact with any one of the circuit elements; a second conductive path electrically connected between the first penetrating electrode and the third penetrating electrode without being in contact with any one of the circuit elements; and a third conductive path electrically connected between the second penetrating electrode and the fourth penetrating electrode without being in contact with any one of the circuit elements.

A according to this aspect of the present invention, it is possible to connect one terminal to each of the first to fourth penetrating electrodes, even when the size (diameter) of each of the first to fourth penetrating electrodes is reduced along with the progress of miniaturization (downsizing) of the semiconductor chip.

As a result, even when the size (diameter) of each of the first to fourth penetrating electrodes is reduced, it is possible to accurately measure the resistance values of the first to fourth penetrating electrodes by using the four-terminal method.

In another aspect of the present invention, there is provided a method of measuring resistance of a semiconductor chip, the method includes: forming a plurality of circuit elements and first to fourth penetrating electrodes that penetrating the semiconductor chip; and measuring a voltage between the third and fourth penetrating electrodes while supplying current from the first penetrating electrode to the second penetrating electrode without passing through any one of the circuit elements.

In still another aspect of the present invention, there is provided a semiconductor device that includes: a semiconductor substrate; a plurality of circuit elements formed on the semiconductor substrate; first and second penetrating electrodes each penetrating the semiconductor substrate; a first conductive path passing current from the first penetrating electrode to second penetrating electrode without being in contact with any one of the circuit elements; a third penetrating electrode penetrating the semiconductor substrate and configured to have substantially the same potential as that of the first penetrating electrode; and a fourth penetrating electrode penetrating the semiconductor substrate and configured to have substantially the same potential as that of the second penetrating electrode.

### BRIEF DESCRIPTION OF THE DRAWINGS

FIG. 1 is a cross-sectional view illustrating a schematic configuration of a stacked-type semiconductor device according to a first embodiment of the present invention;

FIG. 2 is a plan view illustrating a schematic configuration of a semiconductor chip according to the first embodiment as viewed from a side of a wiring substrate illustrated in FIG. 1;

FIG. 3 is an enlarged view indicative of the cut surface of the semiconductor chip illustrated in FIG. 1;

FIG. 4 is a plan view indicative of the semiconductor chip of FIG. 3 as viewed in a direction denoted by an arrow D;

FIG. 5 is a schematic view illustrating a state where resistance values of first to fourth penetrating electrodes of the semiconductor chip are measured by using a four-terminal resistance measuring device;

FIG. 6 is a view indicative of an embodiment of an equivalent circuit of the four-terminal resistance measuring device 130 illustrated in FIG. 5 used at a time of measuring the resistance values using the four-terminal method;

FIG. 7 is a cross-sectional view of a semiconductor chip according to a second embodiment of the present invention;

FIG. 8 is a plan view indicative of the semiconductor chip of FIG. 7 as viewed in a direction denoted by an arrow D;

FIG. 9 is a schematic view illustrating a state where resistance values of first to fourth penetrating electrodes of the semiconductor chip illustrated in FIG. 7 are measured by using a four-terminal resistance measuring device;

FIG. 10 is a view illustrating an equivalent circuit of the four-terminal resistance measuring device 130 illustrated in FIG. 9 used at a time of measuring the resistance values using the four-terminal method;

FIG. 11 is a block diagram of a schematic configuration of a semiconductor chip according to a third embodiment;

FIG. 12 is a cross-sectional view of a main part of the semiconductor chip illustrated in FIG. 11; and

FIG. 13 is a plan view indicative of the semiconductor chip of FIG. 12 as viewed in a direction denoted by an arrow D.

### DETAILED DESCRIPTION OF THE EMBODIMENTS

Embodiments of the present invention will be described in detail below with reference to the accompanying drawings. It should be noted that the drawings are intended to illustrate configurations of the embodiments of the present invention, and a size, a thickness, and a dimension of each component shown in these drawings are not necessarily equal to the actual size, thickness, and dimension of each component of a stacked-type semiconductor device and a semiconductor chip. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

### First Embodiment

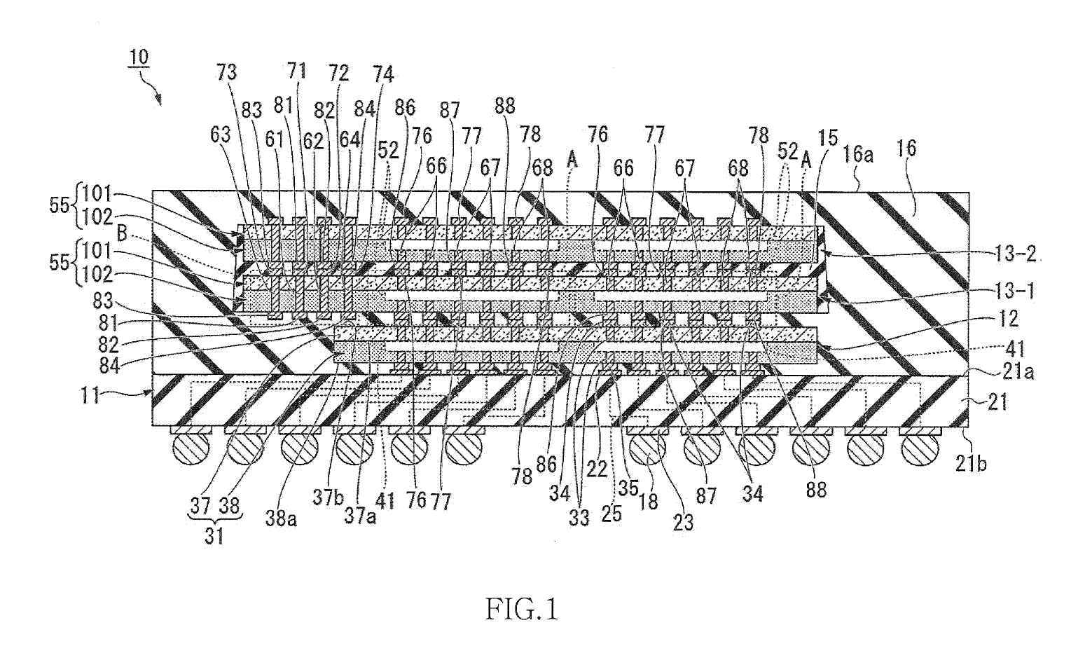

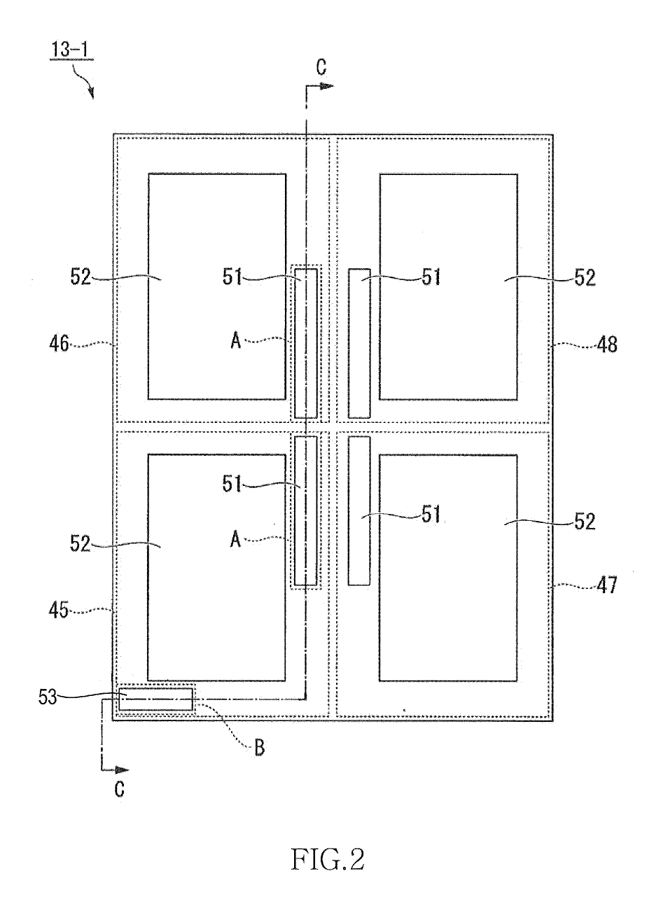

A stacked-type semiconductor device according to the first embodiment of the present invention will be explained with reference to FIGS. 1 and 2. A cross-sectional surface of a semiconductor chip 13-1 shown in FIG. 1 corresponds to a cross section of the semiconductor chip 13-1 taken along a C-C line of FIG. 2 described below.

An area A of FIG. 1 corresponds to the area A of FIG. 2, and an area B of FIG. 1 corresponds to the area B of FIG. 2.

As shown in FIG. 1, a stacked-type semiconductor device 10 according to the first embodiment has a wiring substrate (package substrate), a control semiconductor chip 12, semiconductor chips 13-1 and 13-2, a first encapsulating resin 15, a second encapsulating resin 16, and a plurality of external connection terminals 18.

The wiring substrate 11 has a substrate body 21, a plurality of connection pads 22, a plurality of external connection pads 23, and a plurality of wiring patterns 25. The substrate body 21 has a plate-like shape. For example, an insulating resin substrate may be used as the substrate body 21.

The connection pads 22 are formed on a front surface 21a of the substrate body 21. The connection pads 22 are pads on which the control semiconductor chip 12 is mounted. The external connection pads 23 are formed on a rear surface 21b of the substrate body 21.

The wiring patterns 25 are provided inside the substrate body 21. Each of the wiring patterns 25 has one end connected to an associated one of the connection pads 22 and the other end connected to an associated one of the external connection pads 23, thereby electrically connecting the associated one of the connection pads 22 and the associated one of external connection pads 23.

The control semiconductor chip 12 has a control chip body 31, a plurality of penetrating electrodes 33, a plurality of first bump electrodes 34, and a plurality of second bump electrodes 35.

The control chip body 31 has a semiconductor substrate 37 and a circuit element layer 38. The circuit element layer 38 is disposed on a front surface (main surface) 37a of the semiconductor substrate 37. For example, a monocrystalline silicon substrate may be used as the semiconductor substrate 37.

The circuit element layer 38 has a multi-level wiring structure including a plurality of stacked interlayer dielectric films (not illustrated) and a not illustrated a plurality of wiring layers. The multi-level wiring structure includes wiring patterns each includes via holes provided in the dielectric films and interconnection lines provided as the wiring layers.

The circuit element layer 38 has an internal circuit 41. The internal circuit 41 has a control circuit (not illustrated) that mediates exchange of information between, e.g., wiring substrate 11 and semiconductor chips 13-1 and 13-2.

Although the penetrating electrodes 33 and internal circuit 41 appear in the same cross section for descriptive purpose in FIG. 1, a configuration may be possible in which the penetrating electrodes 33 and internal circuit 41 are not formed in the same cross section.

The penetrating electrodes 33 penetrate the control chip body 31. The plurality of penetrating electrodes 33 are electrically connected to the internal circuit 41. Specifically, the penetrating electrodes 33 are electrically connected to the internal circuit 41 through the wiring pattern formed in the circuit element layer 38.

The penetrating electrodes 33 each have one end surface exposed from a rear surface 37b of the semiconductor substrate 37 and the other end surface exposed from a front surface 38a of the circuit element layer 38.

The first bump electrodes 34 are formed on the one end surface of the penetrating electrodes 33 and protrudes from the rear surface 37b of the semiconductor substrate 37.

The second bump electrodes 35 are formed on the other end surface of the penetrating electrodes 33 and protrudes from the front surface 38a of the circuit element layer 38. The second bump electrodes 35 are connected to the connection pads 22 of the wiring substrate 11.

In other words, the control semiconductor chip 12 is flip-chip mounted on the connection pads 22. This allows electrical connection between the control semiconductor chip 12 and wiring substrate 11.

Turning to FIG. 2, the same reference numerals are given to the same constituent elements as those of the stacked-type semiconductor device 10 illustrated in FIG. 1. Further, in FIG. 2, the area A indicates a formation area of a penetrating electrode group 51, and the area B indicates a formation area of a penetrating electrode group 53 for resistance value measurement.

Further, in FIG. 2, a wide-IO DRAM which is a type of memory semiconductor chips is exemplified as the semiconductor chip 13-1.

First, a configuration of the semiconductor chip 13-1 will be described with reference to FIG. 2. The semiconductor chip 13-1 is the wide-IO DRAM and has first to fourth channels 45 to 48.

The first channel 45 is a DRAM and has the penetrating electrode group 51 including a plurality of terminals each receiving data, a command, and an address, a storage area section 52 including an internal circuit and a memory cell array, and the penetrating electrode group 53 for resistance value measurement.

The penetrating electrode group 53 for resistance value measurement is formed at a corner portion of the first channel 45 so as to be spaced apart from the penetrating electrode group 51.

The second to fourth channels 46 to 48 are also DRAMs and each have the penetrating electrode group 51 including a plurality of terminals each receiving data, a command, and an address and the storage area section 52 including a plurality of circuit elements constituting various circuits such as an internal circuit and a memory cell array.

Hereinafter, the storage area section 52 is sometimes used in referring to the circuit element included in the storage area section 52.

That is, the second to fourth channels 46 to 48 each have the same configuration as that of the first channel 45 except that they do not have the penetrating electrode group 53 for resistance value measurement.

The penetrating electrode group 51 constituting each of the first to fourth channels 45 to 48 is disposed at a center of the semiconductor chip 13-1.

Although the penetrating electrode group 53 for resistance value measurement is provided in the first channel 45 in FIG. 2, the formation location of the penetrating electrode group 53 for resistance value measurement is not limited to this, but the penetrating electrode group 53 for resistance value measurement may be provided in at least any one of the first to fourth channels 45 to 48.

Further, although the penetrating electrode group 53 for resistance value measurement is disposed spaced apart from the penetrating electrode group 51 in FIG. 2, the penetrating electrode group 53 for resistance value measurement may be disposed adjacent to the penetrating electrode group 51.

Alternatively, the penetrating electrode group 53 for resistance value measurement may be formed as a part of the penetrating electrode group 51.

The first to fourth channels 45 to 48 can perform independently operation such as read operation, write operation, refresh operation, etc., of each other under control of the internal circuit 41 provided in the control semiconductor chip 12 illustrated in FIG. 1.

Although the four DRAMs are provided in the semiconductor chip 13-1 in FIG. 2, the number of the DRAMs is not limited to four.

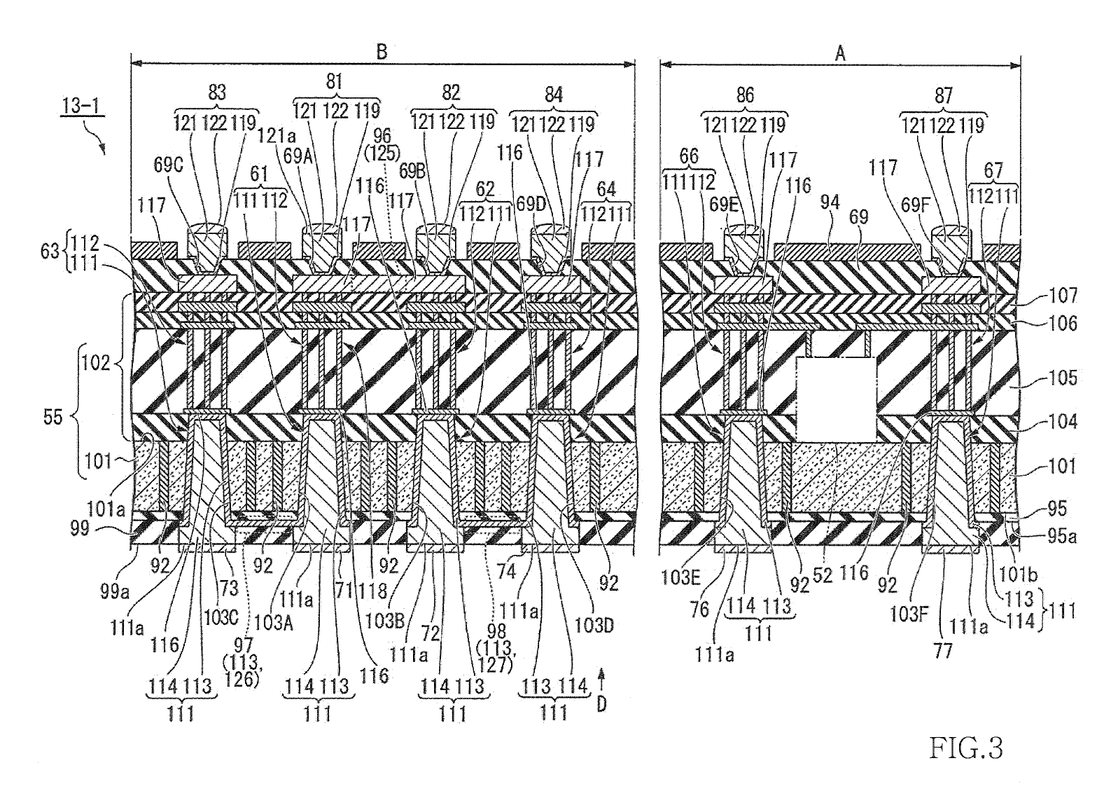

Turning to FIG. 3, the same reference numerals are given to the same constituent elements as those of the semiconductor chip 13-1 illustrated in FIG. 2. Further, the area A illustrated in FIG. 3 corresponds to the area A of FIG. 2, and the area B illustrated in FIG. 3 corresponds to the area B of FIG. 2.

Although the storage area section 52 and the area A appear in the same cross section for descriptive purpose in FIG. 3, the storage area section 52 may be provided outside the area A as viewed from above, as illustrated in FIG. 2.

Further, although not illustrated in FIG. 3, a signal penetrating electrode 68 illustrated in FIG. 1 has substantially the same configuration as those of a power supply penetrating electrode 66 and a ground penetrating electrode 67.

The following describes a concrete configuration of the semiconductor chip 13-1 with reference to FIG. 3.

The semiconductor chip 13-1 has a semiconductor chip body 55, first to fourth penetrating electrodes 61 to 64, the power supply penetrating electrode 66, the ground penetrating electrode 67, the signal penetrating electrode 68 (not illustrated in FIG. 3), a first protecting film 69, first bump electrodes 71 to 74, 76 to 78, second bump electrodes 81 to 84, 86 to 88, an insulating ring 92, a second protecting film 94, an insulating layer 95, first to third conductive paths 96 to 98, and a third protecting film 99.

The semiconductor chip body 55 has a semiconductor substrate 101 and a circuit element layer 102. The semiconductor substrate 101 is a substrate formed into a rectangular shape and may be a monocrystalline silicon substrate.

The semiconductor substrate 101 has through holes 103A, 103B, 103C, 103D, 103E, and 103F penetrating therethrough.

A part of the first penetrating electrode 61 (through substrate conductor) is disposed in the through hole 103A, and a part of the second penetrating electrode 62 (through substrate conductor) is disposed in the through hole 103B. A part of the third penetrating electrode 63 (through substrate conductor) is disposed in the through hole 103C, and a part of the fourth penetrating electrode 64 (through substrate conductor) is disposed in the through hole 103D.

A part of the power supply penetrating electrode 66 (through substrate conductor) is disposed in the through hole 103E, and a part of the ground penetrating electrode 67 (through substrate conductor) is disposed in the through hole 103F.

The circuit element layer 102 is provided on a front surface 101a (main surface) of the semiconductor substrate 101. The circuit element layer 102 has a multi-level wiring structure including a plurality of interlayer dielectric films 104 to 107, the storage area section 52 including the internal circuit, and a plurality of wiring layers. The multi-level wiring structure includes wiring patterns each includes via holes provided in the dielectric films and interconnection lines provided as the wiring layers.

The plurality of interlayer dielectric films 104, 105, 106, and 107 (e.g., a silicon oxide (SiO₂ film)) are stacked on the front surface 101a in the order mentioned.

The first to fourth penetrating electrodes 61 to 64 are formed so as to penetrating the semiconductor chip body 55 corresponding to the area B (formation area of the penetrating electrode group 53 for resistance value measurement). The first to fourth penetrating electrodes 61 to 64 are dummy electrodes for resistance value measurement used for measuring resistance values thereof based on the four-terminal method. In other words, the first to fourth penetrating electrodes 61 to 64 constitute the penetrating electrode group 53 for resistance value measurement illustrated in FIG. 2.

The first penetrating electrode 61 has a through substrate conductor 111 (Si through-via) and a multilayer wiring section 112. Individual layers of the multilayer wiring section 112 are formed as a plurality of wiring layers in the multi-level wiring structure.

The through substrate conductor 111 has a seed layer 113 covering an inner surface of the through hole 103A exposing a lower surface of a pad section 116 (one of constituent elements of the multilayer wiring section 112) to be described later and a conductive film 114 (specifically, a metal film (e.g., Cu film)) that fills the through hole 103A through the seed layer 113.

With the above configuration, the through substrate conductor 111 is electrically connected to the multilayer wiring section 112. Further, formation of the through substrate conductor 111 obtained by filling the through hole 103A with the conductive film 114 can reduce a resistance value of the first penetrating electrode 61.

The seed layer 113 can be formed by PVD or CVD method and the conductive film 114 can be formed by a plating method.

The through substrate conductor 111 has a protruding portion protruding from the insulating layer 95 disposed on a rear surface 101b of the semiconductor substrate 101. The protruding portion has a width wider than that of a part of the through substrate conductor 111 that is disposed within the through hole 103A. The protruding portion has an electrode-forming surface 111a (end surface of the first penetrating electrode 61 exposed from the rear surface 101b of the semiconductor substrate 101) on which the first bump electrode 71 is to be formed.

The multilayer wiring section 112 penetrates the circuit element layer 102 and has a lowermost interconnection pad 116, an uppermost interconnection pad 117, and a wiring pattern 118.

The lowermost interconnection pad 116 is provided on an upper surface of the interlayer dielectric film 104 which is the lowermost layer of the plurality of interlayer dielectric films 104 to 107. The uppermost interconnection pad 117 is provided on an upper surface of the interlayer dielectric film 107 which is the uppermost layer of the plurality of interlayer dielectric films 104 to 107.

The wiring pattern 118 is provided inside the interlayer dielectric films 105, 106, and 107 which are positioned between the lowermost interconnection pad 116 and uppermost interconnection pad 117 and is constituted by a plurality of vias and interconnection pads. The wiring pattern 118 has one end connected to an upper surface of the lowermost interconnection pad 116 and the other end connected to a lower surface of the uppermost interconnection pad 117.

With the above configuration, the wiring pattern 118 electrically connects the lowermost interconnection pad 116 and uppermost interconnection pad 117.

The second penetrating electrode 62 has the same configuration as that of the first penetrating electrode 61 and has the through substrate conductor 111 that fills the through hole 103B and the multilayer wiring section 112.

The third penetrating electrode 63 has the same configuration as that of the first penetrating electrode 61 and has the through substrate conductor 111 that fills the through hole 103C and the multilayer wiring section 112. The third penetrating electrode 63 assumes substantially the same potential as that of the first penetrating electrode 61.

The fourth penetrating electrode 64 has the same configuration as that of the first penetrating electrode 61 and has the through substrate conductor 111 that fills the through hole 103D and the multilayer wiring section 112. The fourth penetrating electrode 64 assumes substantially the same potential as that of the second penetrating electrode 62.

The first to fourth penetrating electrodes 61 to 64 are not electrically connected to any one of the circuit elements constituting the storage area section 52.

The power supply penetrating electrode 66, ground penetrating electrode 67, and signal penetrating electrode 68 (which is not illustrated in FIG. 3) are formed so as to penetrate the semiconductor chip body 55 corresponding to the area A (formation area of the penetrating electrode group 51).

The power supply penetrating electrode 66, ground penetrating electrode 67, and signal penetrating electrode 68 are electrically connected to the control semiconductor chip 12 and the semiconductor chip 13-2.

The plurality of power supply penetrating electrodes 66, plurality of ground penetrating electrodes 67, and plurality of signal penetrating electrodes 68 constitute the penetrating electrode group 51 (see FIGS. 1 and 2).

The power supply penetrating electrode 66 has the same configuration as that of the first penetrating electrode 61 and has the through substrate conductor 111 that fills the through hole 103E and the multilayer wiring section 112. The power supply penetrating electrode 66 is electrically connected to the storage area section 52 through the wiring pattern provided in the interlayer dielectric films 105 and 106.

The ground penetrating electrode 67 has the same configuration as that of the first penetrating electrode 61 and has the through substrate conductor 111 that fills the through hole 103F and the multilayer wiring section 112. The ground penetrating electrode 67 is electrically connected to the storage area section 52 including the circuit elements through the wiring pattern provided in the interlayer dielectric films 105 and 106.

The signal penetrating electrode 68, which is not illustrated in FIG. 3, has the same configuration as that of the first penetrating electrode 61 and has the through substrate conductor 111 and the multilayer wiring section 112. As is the case with the power supply penetrating electrode and ground penetrating electrode 67, the signal penetrating electrode 68 is electrically connected to the storage area section 52 including the circuit elements through the wiring pattern.

Although the power supply penetrating electrode 66, ground penetrating electrode 67, and signal penetrating electrode 68 are electrically connected to the storage area section 52 through the wiring pattern provided in the interlayer dielectric films 105 and 106 in the first embodiment, the formation location of the wiring pattern is not limited to this.

For example, the wiring pattern may be provided so as to electrically connect the uppermost interconnect pad 117 and storage area section 52. Alternatively, the wiring pattern may be provided so as to electrically connect the lowermost interconnection pad 116 and storage area section 52.

The first protecting film 69 is provided on an upper surface of the interlayer dielectric film 107 so as to cover a part of the wiring layer 117. For example, an SiON film may be used as the first protecting film 69. The first protecting film 69 has opening portions 69A, 69B, 69C, 69D, 69E, and 69F.

The opening portion 69A exposes therethrough apart (end of the first penetrating electrode 61) of an upper surface of the uppermost interconnection pad 117 constituting the first penetrating electrode 61, and the opening portion 69B exposes therethrough a part (end of the second penetrating electrode 62) of the upper surface of the uppermost interconnection pad 117 constituting the second penetrating electrode 62.

The opening portion 69C exposes therethrough a part (end of the third penetrating electrode 63) of the upper surface of the uppermost interconnection pad 117 constituting the third penetrating electrode 63, and the opening portion 69D exposes therethrough a part (end of the fourth penetrating electrode 64) of the upper surface of the uppermost interconnection pad 117 constituting the fourth penetrating electrode 64.

The opening portion 69E exposes therethrough apart (end of the power supply penetrating electrode 66) of the upper surface of the uppermost interconnection pad 117 constituting the power supply penetrating electrode 66, and the opening portion 69F exposes therethrough a part (end of the ground penetrating electrode 67) of the upper surface of the uppermost interconnection pad 117 constituting the ground penetrating electrode 67.

Although not illustrated in FIG. 3, an opening portion exposing therethrough a part (end of the signal penetrating electrode 68) of the upper surface of the uppermost interconnection pad 117 constituting the signal penetrating electrode 68 is formed in the first protecting film 69.

Referring to FIG. 3, the first bump electrode 71 is formed so as to cover the electrode-forming surface 111a of the first penetrating electrode 61. For example, a plating layer may be used as the first bump electrode 71.

The first bump electrode 72 is formed so as to cover the electrode-forming surface 111a (end surface) of the second penetrating electrode 62. The first bump electrode 73 is formed so as to cover the electrode-forming surface 111a of the third penetrating electrode 63. The first bump electrode 74 is formed so as to cover the electrode-forming surface 111a of the fourth penetrating electrode 64. The first bump electrodes 72 to 74 each have the same configuration as that of the first bump electrode 71.

The first bump electrode 76 is formed so as to cover the electrode-forming surface 111a of the power supply penetrating electrode 66. The first bump electrode 77 is formed so as to cover the electrode-forming surface 111a of the ground penetrating electrode 67.

The first bump electrodes 71 to 77 each protrude from a lower surface 99a of the third protecting film 99. Although not illustrated in FIG. 3, the first bump electrode 78 illustrated in FIG. 1 is formed so as to cover the electrode-forming surface 111a (not illustrated) of the signal penetrating electrode 67 and to protrude from the lower surface 99a of the third protecting film 99.

The second bump electrode 81 has a seed layer 119 that covers an inner surface of the opening portion 69A, a conductive film 121 (e.g., Cu film) that fills the opening portion 69A through the seed layer 119, and a solder 122.

A part of the conductive film 121 protrudes from an upper surface of the second protecting film 94 disposed on the first protecting film 69, and a width of the protruding portion is wider than a diameter of the opening portion 69A. The protruding portion has a flat solder-forming surface 121a. The solder 122 is provided on the solder-forming surface 121a of the conductive film 121.

The second bump electrode 81 having the above configuration is connected to one end of the first penetrating electrode 61.

The second bump electrode 82 has the same configuration as that of the second bump electrode 81 and is disposed in the opening portion 69B. With this configuration, the second bump electrode 82 is electrically connected to one end of the second penetrating electrode 62.

The second bump electrode 83 has the same configuration as that of the second bump electrode 81 and is disposed in the opening portion 69C. With this configuration, the second bump electrode 83 is electrically connected to one end of the third penetrating electrode 63.

The second bump electrode 84 has the same configuration as that of the second bump electrode 81 and is disposed in the opening portion 69D. With this configuration, the second bump electrode 84 is electrically connected to the fourth penetrating electrode 64.

The second bump electrode 86 has the same configuration as that of the second bump electrode 81 and is disposed in the opening portion 69E. With this configuration, the second bump electrode 86 is electrically connected to the power supply penetrating electrode 66.

The second bump electrode 87 has the same configuration as that of the second bump electrode 81 and is disposed in the opening portion 69F. With this configuration, the second bump electrode 87 is electrically connected to the ground penetrating electrode 67.

Although not illustrated in FIG. 3, the second bump electrode 88 illustrated in FIG. 1 has the same configuration as that of the second bump electrode 81.

As illustrated in FIG. 1, the above configured second bump electrodes 86 to 88 of the semiconductor chip 13-1 are each connected to the first bump electrodes 34 provided in the control semiconductor chip 12 through the solder 122 (see FIG. 3).

That is, the semiconductor chip 13-1 is flip-chip mounted on the control semiconductor chip 12 mounted on the wiring substrate 11.

This allows the semiconductor chip 13-1 to electrically be connected to the control semiconductor chip 12 and wiring substrate 11.

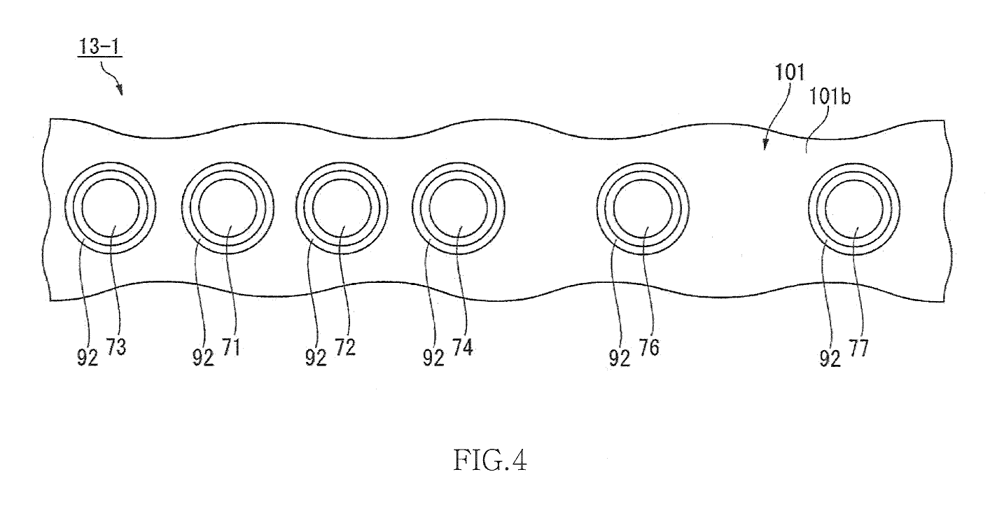

Turning to FIG. 4, the insulating layer 95 and the third protecting film 99 provided on the rear surface 101b of the semiconductor substrate 101 illustrated in FIG. 3 are omitted for simplicity.

Referring to FIGS. 3 and 4, the insulating rings 92 are cylindrical insulator penetrating the semiconductor substrate 101 and are disposed so as to surround individual substrate penetrating electrodes 111 constituting the first to fourth penetrating electrodes 61 to 64, power supply penetrating electrode 66, and ground penetrating electrode 67.

In other words, one insulation ring 92 is provided for each substrate penetrating electrode 111.

Further, the insulating ring 92 is provided for the substrate penetrating electrode 111 constituting the signal penetrating electrode 68 (see FIG. 1) which is not illustrated in FIGS. 3 and 4 so as to surround the substrate penetrating electrode 111.

As a result, the first to fourth penetrating electrodes 61 to 64, power supply penetrating electrode 66, ground penetrating electrode 67, and signal penetrating electrode 68 are electrically isolated to each other by the insulating rings 92.

The insulating rings 92 are each formed by filling a cylindrical groove penetrating the semiconductor substrate 101 with an insulating film (e.g., a silicon oxide film (SiO₂ film)).

Referring to FIG. 3, the second protecting film 94 is provided on the first protecting film 69. For example, a polyimide film may be used as the second protecting film 94.

The insulating layer 95 is disposed so as to cover the rear surface 101b of the semiconductor substrate 101 in which the plurality of insulating rings 92 are formed.

The first conductive path 96 is a first conductive pattern 125 provided on the interlayer dielectric film 107. The first conductive pattern 125 is connected, not through the circuit elements (elements constituting the storage area section 52) provided in the circuit element layer 102, but directly to the uppermost interconnection pad 117 (one of constituent elements of the multilayer wiring section 112) constituting the first penetrating electrode 61 and the uppermost interconnection pad 117 (one of constituent elements of the multilayer wiring section 112) constituting the second penetrating electrode 62.

As a result, the first conductive pattern 125 electrically connects the first and second penetrating electrodes 61 and 62 directly, not through the circuit elements provided in the circuit element layer 102.

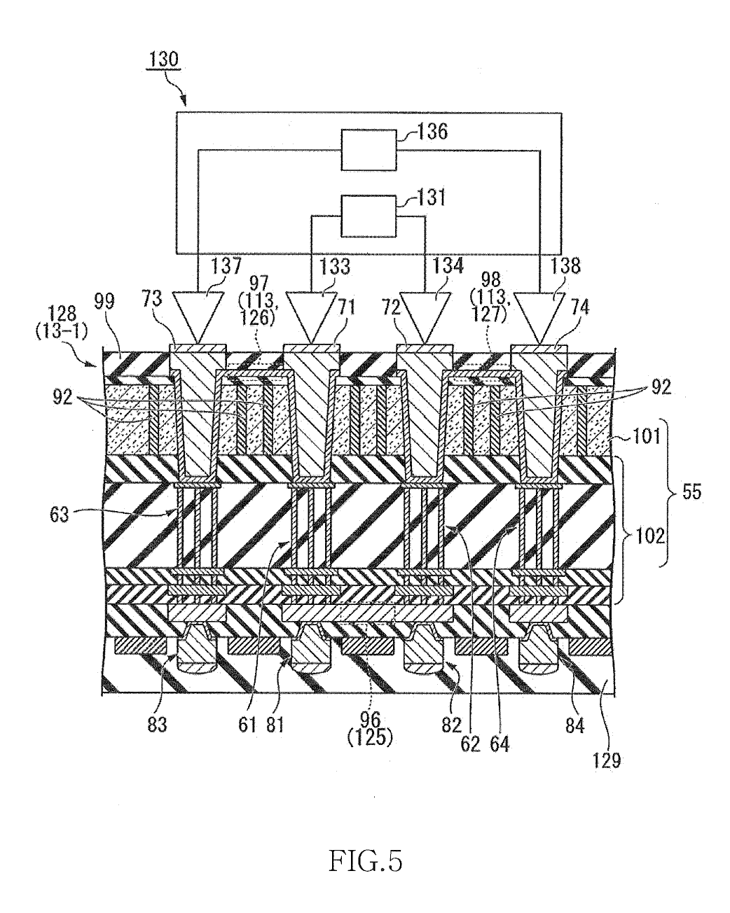

When a four-terminal resistance measuring device 130 (to be described later with reference to FIG. 5) is used to measure resistance values of the first to fourth penetrating electrodes 61 to 64, the first conductive path 96 carries current to be supplied to the first penetrating electrode 61 from the first penetrating electrode 61 to second penetrating electrode 62, not through any of the plurality of circuit elements.

The first conductive pattern 125 can be obtained by forming a conductive film (e.g., an aluminum film) serving as a base material of the uppermost interconnection pad 117 constituting the first and second penetrating electrodes 61 and 62 on the interlayer dielectric film 107 and patterning the formed conductive film by a photolithography technique and a dry-etching technique.

That is, the first conductive pattern 125 can be formed together with the uppermost interconnection pad 117 constituting the first and second penetrating electrodes 61 and 62 in a formation process of the uppermost interconnection pad 117, eliminating the need to provide additional formation process of the first conductive pattern 125.

Thus, it is possible to form the first conductive pattern 125 without increasing production cost of the semiconductor chip 13-1.

Although the first conductive pattern 125 is disposed on the interlayer dielectric film 107 in FIG. 3, the formation location of the first conductive pattern 125 is not limited to this.

For example, the first conductive pattern 125 electrically connecting the first and second penetrating electrodes 61 and 62 may be disposed between the wiring patterns 118 (e.g., on the interlayer dielectric film 106 or on the interlayer dielectric film 105) of the first and second penetrating electrodes 61 and 62.

The second conductive path 97 is a second conductive pattern 126 disposed on the rear surface 101b side of the semiconductor substrate 101. The second conductive pattern 126 is constituted by a part (first part functioning as the second conductive path 97 and disposed on a lower surface 95a of the insulating layer 95) of the seed layer 113 that is disposed from the inner surface of the through hole 103A in which the substrate penetrating electrode 111 of the first penetrating electrode 61 is disposed to the inner surface of the through hole 103C in which the third penetrating electrode 63 is disposed.

As a result, the second conductive pattern 126 is connected, not through the circuit elements (elements constituting the storage area section 52) provided in the circuit element layer 102, but directly to the substrate penetrating electrode 111 constituting the first penetrating electrode 61 and the substrate penetrating electrode 111 constituting the third penetrating electrode 63.

In other words, the second conductive pattern 126 electrically connects the first and third penetrating electrodes 61 and 63 directly, not through the circuit elements provided in the circuit element layer 102.

When a four-terminal resistance measuring device 130 (to be described later with reference to FIG. 5) is used to measure resistance values of the first to fourth penetrating electrodes 61 to 64, the second conductive path 97 makes the first penetrating electrode 61 and third penetrating electrodes 63 conductive substantially without carrying current.

The second conductive pattern 126 is formed by making the seed layer 113 positioned between the through hole 103A and through hole 103C remain in a process of removing an unnecessary part of the seed layer 113 which has been used as a power feeding layer for forming the conductive film 114 using an electrolytic plating method.

That is, the second conductive pattern 126 can be formed without providing additional formation process of the second conductive pattern 126. Thus, it is possible to form the second conductive pattern 126 without increasing production cost of the semiconductor chip 13-1.

The third conductive path 98 is a third conductive pattern 127 disposed on the rear surface 101b side of the semiconductor substrate 101. The third conductive pattern 127 is constituted by a part (second part functioning as the third conductive path 98 and disposed on the lower surface 95a of the insulating layer 95) of the seed layer 113 that is disposed from the inner surface of the through hole 103B in which the substrate penetrating electrode 111 of the second penetrating electrode 62 is disposed to the inner surface of the through hole 103D in which the fourth penetrating electrode 64 is disposed.

As a result, the third conductive pattern 127 is connected, not through the circuit elements (elements constituting the storage area section 52) provided in the circuit element layer 102, but directly to the substrate penetrating electrode 111 constituting the second penetrating electrode 62 and the substrate penetrating electrode 111 constituting the fourth penetrating electrode 64.

In other words, the third conductive pattern 127 electrically connects the second and fourth penetrating electrodes 62 and 64 directly, not through the circuit elements provided in the circuit element layer 102.

When a four-terminal resistance measuring device 130 (to be described later with reference to FIG. 5) is used to measure resistance values of the first to fourth penetrating electrodes 61 to 64, the third conductive path 98 makes the second penetrating electrode 62 and fourth penetrating electrodes 64 conductive substantially without carrying current.

The third conductive pattern 127 is formed by making the seed layer 113 positioned between the through hole 103B and through hole 103D remain in a process of removing an unnecessary part of the seed layer 113 which has been used as a power feeding layer for forming the conductive film 114 using an electrolytic plating method.

That is, the third conductive pattern 127 can be formed without providing additional formation process of the third conductive pattern 127. Thus, it is possible to form the third conductive pattern 127 without increasing production cost of the semiconductor chip 13-1.

The third protecting film 99 is provided on the lower surface 95a of the insulating later 95 so as to cover the second and third conductive paths 97 and 98 (second and third conductive pattern 126 and 127). The third protecting film 99 has a function of protecting the second and third conductive paths 97 and 98.

Referring to FIG. 1, the semiconductor chip 13-2 has the same configuration as that of the semiconductor chip 13-1. That is, the semiconductor chip 13-2 has the same configuration as that of the semiconductor chip 13-1 illustrated in FIGS. 2 to 4.

The thus configured semiconductor chip 13-2 has the same effect as that of the semiconductor chip 13-1. Specifically, even when the size (diameter) of each of the first to fourth penetrating electrodes 61 to 64 is reduced, it is possible to accurately measure the resistance values of the first to fourth penetrating electrodes 61 to 64 by using the four-terminal method.

The semiconductor chip 13-2 having the above configuration is flip-chip mounted on the semiconductor chip 13-1.

As a result, the second bump electrode 81 of the semiconductor chip 13-2 is connected to the first bump electrode 71 of the semiconductor chip 13-1, and the second bump electrode 82 of the semiconductor chip 13-2 is connected to the first bump electrode 72 of the semiconductor chip 13-1.

Further, the second bump electrode 83 of the semiconductor chip 13-2 is connected to the first bump electrode 73 of the semiconductor chip 13-1, and the second bump electrode 84 of the semiconductor chip 13-2 is connected to the first bump electrode 74 of the semiconductor chip 13-1.

Further, the second bump electrode 86 of the semiconductor chip 13-2 is connected to the first bump electrode 76 of the semiconductor chip 13-1, and the second bump electrode 87 of the semiconductor chip 13-2 is connected to the first bump electrode 77 of the semiconductor chip 13-1.

Further, the second bump electrode 88 of the semiconductor chip 13-2 is connected to the first bump electrode 78 of the semiconductor chip 13-1.

The first encapsulating resin 15 is provided on the semiconductor chips 13-1 and 13-2 so as to fill a gap between the semiconductor chips 13-1 and 13-2 and cover side walls thereof. For example, an under-fill resin may be used as the first encapsulating resin 15.

The second encapsulating resin 16 is provided on the front surface 21a of the substrate body 21 so as to fill a gap between the semiconductor chip 13-1 and wiring substrate 11, and a gap between the control semiconductor chip 12 and wiring substrate 11, and to encapsulate the control semiconductor chip 12, semiconductor chips 13-1 and 13-2, and first encapsulating resin 15. An upper surface 16a of the second encapsulating resin 16 is flattened.

For example, a mold resin may be used as the second encapsulating resin 16.

The external connection terminals 18 are provided for each external connection pads 23. The external connection terminals 18 are electrically connected to the control semiconductor chip 12 through the wiring substrate 11. For example, a solder ball may be used as the external connection terminals 18.

Turning to FIG. 5, the semiconductor chip 13-1 is illustrated in a cross-sectional view. In FIG. 5, the same reference numerals are given to the same constituent elements as those of the semiconductor chip 13-1 illustrated in FIG. 3.

The following describes a method (measurement method of resistance of the semiconductor chip according to the first embodiment) of measuring the resistance values of the first to fourth penetrating electrodes 61 to 64 provided in the semiconductor chip 13-1 using the four-terminal method with reference to FIG. 5.

First, a semiconductor wafer (e.g., a silicon wafer) having a plurality of chip formation areas and a dicing area for defining the plurality of chip formation areas is prepared.

Subsequently, the semiconductor chip 13-1 illustrated in FIG. 3 is formed in each of the plurality of chip formation areas by a known method to thereby form a semiconductor chip formation base substrate 128 including the plurality of connected semiconductor chips 13-1.

Subsequently, a support member 129 for protecting the second bump electrodes 81 to 84, 86, and 87 is bonded to a surface of the semiconductor chip formation base substrate 128 on a side at which the second bump electrodes 81 to 84, 86, and 87 are formed.

Then, the semiconductor chip formation base substrate 128 to which the support member 129 has been bonded is turned upside down and placed on a suction stage (not illustrated) of the four-terminal resistance measuring device 130.

The following describes a schematic configuration of the four-terminal resistance measuring device 130 with reference to FIG. 5.

The four-terminal resistance measuring device 130 has a current application section 131 (power supply), a pair of current application terminals 133 and 134 connected to the current application section 131, a voltage measurement section 136, a pair of voltage measurement terminals 137 and 138 connected to the voltage measurement section 136, and a stage (not illustrated).

A voltage system of the voltage measurement section 136 has a high input impedance, substantially preventing current from flowing through the voltage measurement section 136.

The current application terminal 133 is a first probe electrode, and the current application terminal 134 is a second probe electrode. The pair of current application terminals 133 and 134 supply current from the first penetrating electrode 61 to the second penetrating electrode 62.

The voltage measurement terminal 137 is a third probe electrode, and the voltage measurement terminal 138 is a fourth probe electrode.

Then, the four terminals (current application terminals 133, 134 and voltage measurement terminals 137, 138) of the four-terminal resistance measuring device 130 are brought into contact with the first bump electrodes 71 to 74.

Specifically, the current application terminal 133 is brought into contact with the first bump electrode 71, the current application terminal 134 is brought into contact with the first bump electrode 72, the power supply measurement terminal 137 is brought into contact with the first bump electrode 73, and the power supply measurement terminal 138 is brought into contact with the first bump electrode 74.

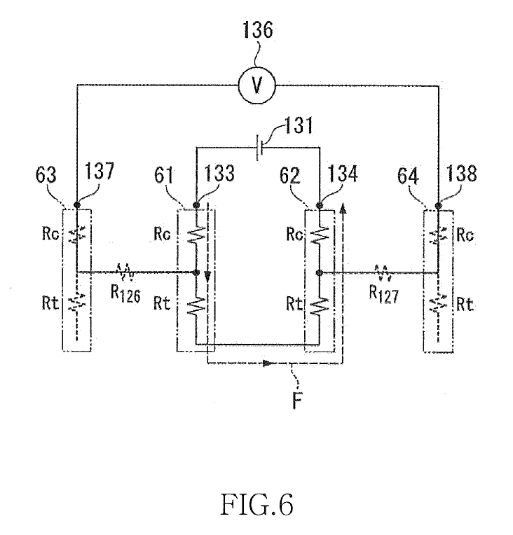

Turning to FIG. 6, the same reference numerals are given to the same constituent elements as those of the structure illustrated in FIG. 5.

The following describes a resistance measurement method using the four-terminal method in which four terminals are connected to the first bump electrodes 71 to 74, respectively, with reference to FIG. 6.

As described above, in this configuration, current does not substantially flow through the voltage measurement section 136. Thus, as denoted by a dashed line F of FIG. 6, current supplied from the current application section 131 of the four-terminal resistance measuring device 130 passes through the first and second penetrating electrodes 61 and 62 and returns to the four-terminal resistance measuring device 130. That is, the current supplied from the current application section 131 does not flow through the third and fourth penetrating electrodes 63 and 64.

A voltage drop occurs between the pair of current application terminals 133 and 134 due to a contact resistance Rc between the current application terminal 133 and first penetrating electrode 61, a contact resistance Rc between the current application terminal 134 and second penetrating electrode 62, a resistance Rt of the first penetrating electrode 61 itself, and a resistance Rt of the second penetrating electrode 62 itself.

Further, current does not flow through a resistance Rt of the third penetrating electrode 63 itself denoted by a dotted line of FIG. 6, a resistance Rt of the fourth penetrating electrode 64 denoted by a dotted line of FIG. 6, a contact resistance Rc between the power supply measurement terminal 137 and third penetrating electrode 63, a contact resistance Rc between the power supply measurement terminal 138 and fourth penetrating electrode 64, a resistance R₁₂₆ of the second conductive pattern 126 electrically connecting the first penetrating electrode 61 and third penetrating electrode 63, and a resistance R₁₂₇ of the third conductive pattern 127 electrically connecting the second penetrating electrode 62 and fourth penetrating electrode 64, so that no voltage drop occurs due to these resistances. In other words, these resistance values give no influence on a voltage measurement value measured by the voltage measurement section 136.

That is, the voltage measurement section 136 detects, as a voltage value, a voltage drop caused due to the resistance between the first and second penetrating electrodes 61 and 62.

Thus, from a known current value I supplied from the current application section 131 of the four-terminal resistance measuring device 130 to the semiconductor chip 13-1 and the detected voltage value, the resistance values of the first to fourth penetrating electrodes 61 to 64 can accurately be measured.

After the measurement of the resistance values of the first to fourth penetrating electrodes 61 to 64, the semiconductor chip formation base substrate 128 is cut along the dicing area into pieces to obtain the plurality of semiconductor chips 13-1.

As described above, the semiconductor chip according to the first embodiment has the first to fourth penetrating electrodes 61 to 64 penetrating the semiconductor chip body 55, the first conductive path 96 (first conductive pattern 125) electrically connecting the first penetrating electrode 61 and second penetrating electrode 62 directly, not through the circuit elements (elements constituting the storage area section 52) provided in the circuit element layer 102, the second conductive path 97 (second conductive pattern 126) electrically connecting the first penetrating electrode 61 and third penetrating electrode 63 directly, not through the circuit elements provided in the circuit element layer 102, and the third conductive path 98 (third conductive pattern 127) electrically connecting the second penetrating electrode 62 and fourth penetrating electrode 64 directly, not through the circuit elements provided in the circuit element layer 102. Thus, it is possible to connect a corresponding terminal to each of the first to fourth penetrating electrodes 61 to 64, even when the size (diameter) of each of the first to fourth penetrating electrodes 61 to 64 is reduced along with the progress of miniaturization (downsizing) of the semiconductor chip 13-1.

As a result, even when the size (diameter) of each of the first to fourth penetrating electrodes 61 to 64 is reduced, it is possible to accurately measure the resistance values of the first to fourth penetrating electrodes 61 to 64 by using the four-terminal method.

Although the wide-IO DRAM which is a memory semiconductor chip is exemplified as the semiconductor chip 13-1 in the first embodiment, the type of the semiconductor chip 13-1 is not limited to this but the present invention may be applied to any type of the semiconductor chip as long as it has the first to fourth penetrating electrodes 61 to 64.

### Second Embodiment

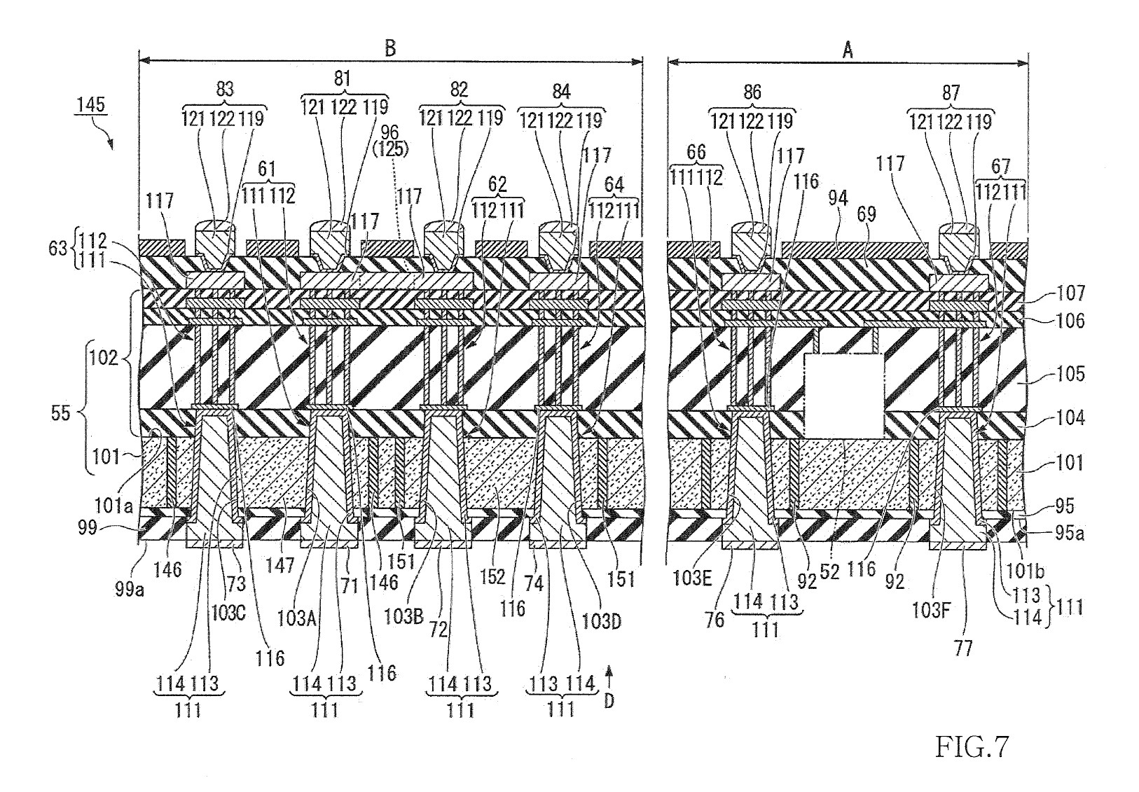

Turning to FIG. 7, the same reference numerals are given to the same constituent elements as those of the semiconductor chip 13-1 illustrated in FIG. 3. In FIG. 7, the wide-IO DRAM which is a memory semiconductor chip is exemplified as a semiconductor chip 145 of the second embodiment.

Referring to FIG. 7, the semiconductor chip according to the second embodiment has the same configuration as that of the semiconductor chip 13-1 except that a first insulating ring 146, a second conductive path 147, a second insulating ring 151, and a third conductive path 152 are provided in place of the insulating ring 92 surrounding the through substrate conductor 111 of each of the first to fourth penetrating electrodes 61 to 64, the second conductive path 97 (a part of the seed layer 113 disposed from the inner surface of the through hole 103A in which the through substrate conductor 111 of the first penetrating electrode 61 is disposed to the inner surface of the through hole 103C in which the third penetrating electrode 63 is disposed, the part being disposed on the lower surface 95a of the insulating layer 95 of the seed layer 113), and the third conductive path 98 (a part of the seed layer 113 disposed from the inner surface of the through hole 103B in which the substrate penetrating electrode 111 of the second penetrating electrode 62 is disposed to the inner surface of the through hole 103D in which the fourth penetrating electrode 64 is disposed, the part being disposed on the lower surface 95a of the insulating layer 95), which are provided in the semiconductor chip 13-1 according to the first embodiment.

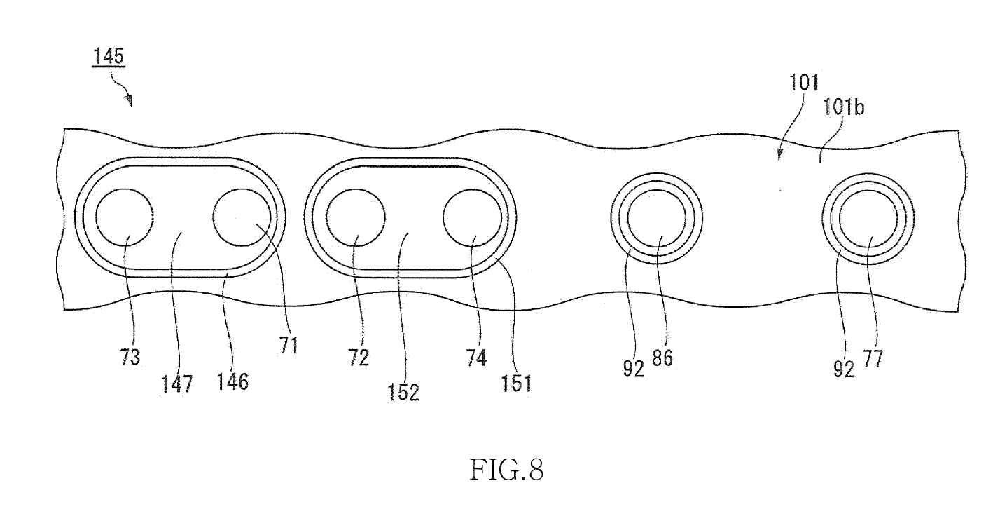

Turning to FIG. 8, the insulating layer 95 and the third protecting film 99 provided on the rear surface 101b of the semiconductor substrate 101 illustrated in FIG. 7 are omitted for simplicity.

Referring to FIGS. 7 and 8, the first insulating ring 146 is a cylindrical insulator penetrating the semiconductor substrate 101, and is disposed so as to surround the through substrate conductor 111 of the first penetrating electrode 61 and the through substrate conductor 111 of the third penetrating electrode 63 (in other words, two penetrating electrodes).

That is, an insulator electrically isolating between the through substrate conductor 111 of the first penetrating electrode 61 and the through substrate conductor 111 of the third penetrating electrode 63 is not provided therebetween.

The first insulating ring 146 can be formed by the same method as that used for formation of the insulating ring 92 and can be formed simultaneously with the insulating ring 92.

The second conductive path 147 is constituted by the semiconductor substrate 101 surrounded by the first insulating ring 146. As a result, the second conductive path 147 electrically connects the through substrate conductor 111 of the first penetrating electrode 61 and the through substrate conductor 111 of the third penetrating electrode 63 substantially without carrying current.

The second conductive path 147 is a conductive path obtained by forming the first insulating ring 146 in the semiconductor substrate 101.

The second insulating ring 151 is a cylindrical insulator penetrating the semiconductor substrate 101, and is disposed so as to surround the through substrate conductor 111 of the second penetrating electrode 62 and the through substrate conductor 111 of the fourth penetrating electrode (in other words, two penetrating electrodes).

That is, an insulator electrically isolating between the through substrate conductor 111 of the second penetrating electrode 62 and the through substrate conductor 111 of the fourth penetrating electrode 64 is not provided therebetween.

The second insulating ring 151 can be formed by the same method as that used for formation of the insulating ring 92 and can be formed simultaneously with the insulating ring 92.

The third conductive path 152 is constituted by the semiconductor substrate 101 surrounded by the second insulating ring 151. As a result, the third conductive path 152 electrically connects the through substrate conductor 111 of the second penetrating electrode 62 and the through substrate conductor 111 of the fourth penetrating electrode 64 substantially without carrying current.

The third conductive path 152 is a conductive path obtained by forming the second insulating ring 151 in the semiconductor substrate 101.

That is, the semiconductor chip 145 of the second embodiment differs from the semiconductor chip 13-1 of the first embodiment in this point. Specifically, the seed layer 113 is used as the second and third conductive paths 97 and 98 in the first embodiment; on the other hand, in the second embodiment, portions of the semiconductor substrate 101 that are surrounded by the first and second insulating rings 146 and 151 are used as second and third conductive paths 147 and 152.

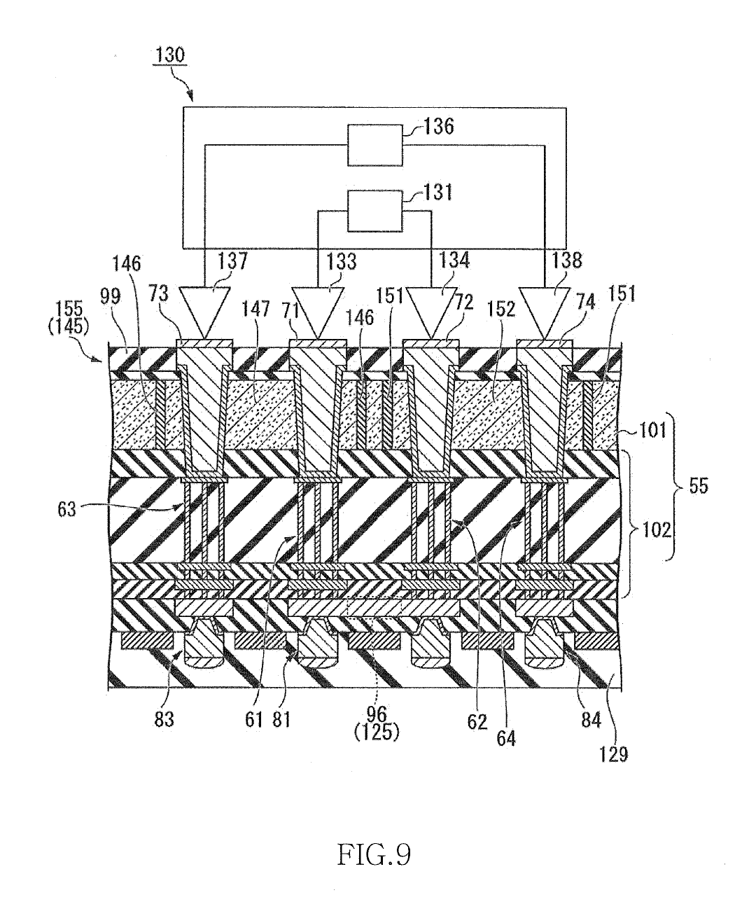

Turning to FIG. 9, the same reference numerals are given to the same constituent elements as those of the four-terminal resistance measuring device 130 illustrated in FIG. 5 and the semiconductor chip 145 illustrated in FIG. 7.

The following describes a method of measuring the resistance values of the first to fourth penetrating electrodes 61 to 64 using the four-terminal resistance measurement device 130 with reference to FIG. 9.

First, a semiconductor wafer (e.g., a silicon wafer) having a plurality of chip formation areas and a dicing area for defining the plurality of chip formation areas is prepared.

Subsequently, the semiconductor chip 145 illustrated in FIG. 7 is formed in each of the plurality of chip formation areas by a known method to thereby form a semiconductor chip formation base substrate 155 including the plurality of connected semiconductor chips 145.

Subsequently, the support member 129 for protecting the second bump electrodes 81 to 84, 86, and 87 is bonded to a surface of the semiconductor chip formation base substrate 155 on a side at which the second bump electrodes 81 to 84, 86, and 87 are formed.

Then, the semiconductor chip formation base substrate 155 to which the support member 129 has been bonded is turned upside down and placed on a suction stage (not illustrated) of the four-terminal resistance measuring device 130.

Then, current is made to flow with the four terminals (current application terminals 133, 134 and voltage measurement terminals 137, 138) of the four-terminal resistance measuring device 130 made to abut against (brought into contact with) the first bump electrodes 71 to 74 to measure the resistance values of the first to fourth penetrating electrodes 61 to 64.

At this time, the current application terminal 133 is made to abut against the first bump electrode 71, the current application terminal 134 is made to abut against the first bump electrode 72, the power supply measurement terminal 137 is made to abut against the first bump electrode 73, and the voltage measurement terminal 138 is made to abut against the first bump electrode 74.

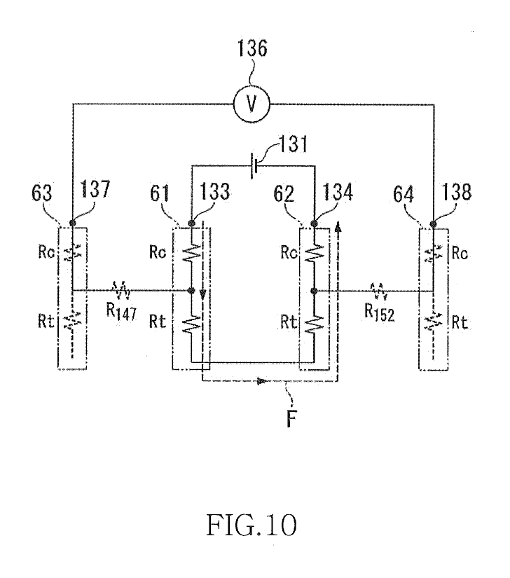

Turning to FIG. 10, the same reference numerals are given to the same constituent elements as those of the structure illustrated in FIGS. 6 and 9.

Referring to FIG. 10, at the resistance value measurement time, a voltage drop occurs between the pair of current application terminals 133 and 134 due to a contact resistance Rc between the current application terminal 133 and first penetrating electrode 61, a contact resistance Rc between the current application terminal 134 and second penetrating electrode 62, a resistance Rt of the first penetrating electrode 61 itself, and a resistance Rt of the second penetrating electrode 62 itself.

Further, current does not flow through a resistance Rt of the third penetrating electrode 63 itself denoted by a dotted line of FIG. 10, a resistance Rt of the fourth penetrating electrode 64 denoted by a dotted line of FIG. 10, a contact resistance Rc between the voltage measurement terminal 137 and third penetrating electrode 63, a contact resistance Rc between the power supply measurement terminal 138 and fourth penetrating electrode 64, a resistance R₁₄₇ of the second conductive path 147 (a part of the semiconductor substrate 101 that is surrounded by the first insulating ring 146) electrically connecting the first penetrating electrode 61 and third penetrating electrode 63, and a resistance R₁₅₂ of the third conductive path 152 (a part of the semiconductor substrate 101 that is surrounded by the second insulating ring 151) electrically connecting the second penetrating electrode 62 and fourth penetrating electrode 64, so that no voltage drop occurs due to these resistances. In other words, these resistance values give no influence on a voltage measurement value measured by the voltage measurement section 136.

That is, the voltage measurement section 136 detects, as a voltage value, a voltage drop caused due to the resistance between the first and second penetrating electrodes 61 and 62.

Thus, from a known current value I supplied from the current application section 131 of the four-terminal resistance measuring device 130 to the semiconductor chip 145 and the detected voltage value, the resistance values of the first to fourth penetrating electrodes 61 to 64 can accurately be measured.

After the measurement of the resistance values of the first to fourth penetrating electrodes 61 to 64, the semiconductor chip formation base substrate 155 is cut along the dicing area into pieces to obtain the plurality of semiconductor chips 145.

In the first embodiment, the seed layer 113 is used as a base material of the second and third conductive patterns 126 and 127, so that the seed layer 113 is formed not only on inner surfaces of the through holes 103A, 103B, 103C, 103D, 103E, and 103F, but also on the lower surface 95a of the insulating layer 95.

However, the inner surface of each of the through holes 103A, 103B, 103C, 103D, 103E, and 103F and lower surface 95a of the insulating layer 95 on which the seed layer 113 is formed are different in surface state (surface property).

Thus, at a time of forming the seed layer 113 using a plating method, it is difficult to control plating conditions such that a layer having the same film quality and same film thickness is formed on surfaces having different surface properties.

On the other hand, in the second embodiment, not the seed layer 113, but the portions of the semiconductor substrate 101 that are surrounded by the first and second insulating rings 146 and 151 are used as the second and third conductive paths 147 and 152, thereby preventing the above-described problem that arises at the formation time of the seed layer 113.

The semiconductor chip 145 of the second embodiment has the same effect as that of the semiconductor chip 13-1 of the first embodiment. Specifically, even when the size (diameter) of each of the first to fourth penetrating electrodes 61 to 64 is reduced, it is possible to accurately measure the resistance values of the first to fourth penetrating electrodes 61 to 64 by using the four-terminal method.

Although the wide-IO DRAM which is a memory semiconductor chips is exemplified as the semiconductor chip 145 in the second embodiment, the type of the semiconductor chip 145 is not limited to this but the present invention may be applied to any type of the semiconductor chip as long as it has the first to fourth penetrating electrodes 61 to 64.

Further, the stacked-type semiconductor device may be formed by stacking the two semiconductor chips 145 in place of the semiconductor chips 13-1 and 13-2 illustrated in FIG. 1.

### Third Embodiment

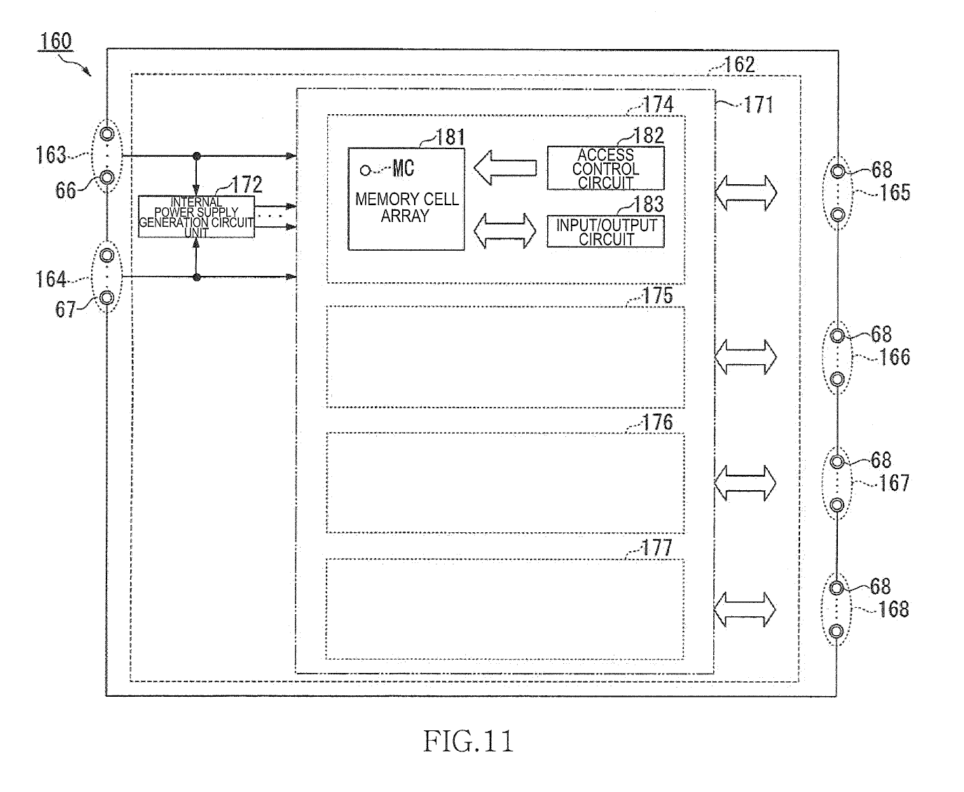

Turning to FIG. 11, the same reference numerals are given to the same constituent elements as those of the structure illustrated in FIG. 1.

Referring to FIG. 11, a semiconductor chip 160 of the third embodiment has an internal circuit 162 including circuit elements, a power supply penetrating electrode group 163 including the plurality of power supply penetrating electrodes 66, a ground penetrating electrode group 164 including the plurality of ground penetrating electrodes 67, and signal penetrating electrode groups 165 to 168 each including the plurality of signal penetrating electrodes 68.

The internal circuit 162 has a function circuit unit 171 and an internal power supply generation circuit unit 172. The function circuit unit 171 has first to fourth channels 174 to 177.

The first channel 174 is electrically connected to the plurality of signal penetrating electrodes 68 constituting the signal penetrating electrode group 165. The first channel 174 exchanges signals with an external device through the signal penetrating electrodes 68.

The first channel 174 has a memory cell array 181 serving as a storage section for storing data, an access control circuit 182, and an input/output circuit 183.

The access control circuit 182 performs control which part of the memory cell array 181 is accessed. The input/output circuit 183 writes data in the memory cell array 181 and outputs data written in the memory cell array 181.

The second to fourth channels 175 to 177 each have the same configuration as that of the first channel 174. The second channel 175 is electrically connected to the plurality of signal penetrating electrodes 68 constituting the signal penetrating electrode group 166. The second channel 175 exchanges signals with an external device through the signal penetrating electrodes 68.

The third channel 176 is electrically connected to the plurality of signal penetrating electrodes 68 constituting the signal penetrating electrode group 167. The third channel 176 exchanges signals with an external device through the signal penetrating electrodes 68.

The fourth channel 177 is electrically connected to the plurality of signal penetrating electrodes 68 constituting the signal penetrating electrode group 168. The fourth channel 177 exchanges signals with an external device through the signal penetrating electrodes 68.

The internal power supply generation circuit unit 172 is electrically connected to the plurality of power supply penetrating electrodes 66 constituting the power supply penetrating electrode group 163, plurality of ground penetrating electrodes 67 constituting the ground penetrating electrode group 164, and function circuit unit 171.

The power supply penetrating electrode group 163 includes the plurality of power supply penetrating electrodes 66. The plurality of power supply penetrating electrodes 66 have the same potential.

The ground penetrating electrode group 164 includes the plurality of ground penetrating electrodes 67. The plurality of ground penetrating electrodes 67 have the same potential.

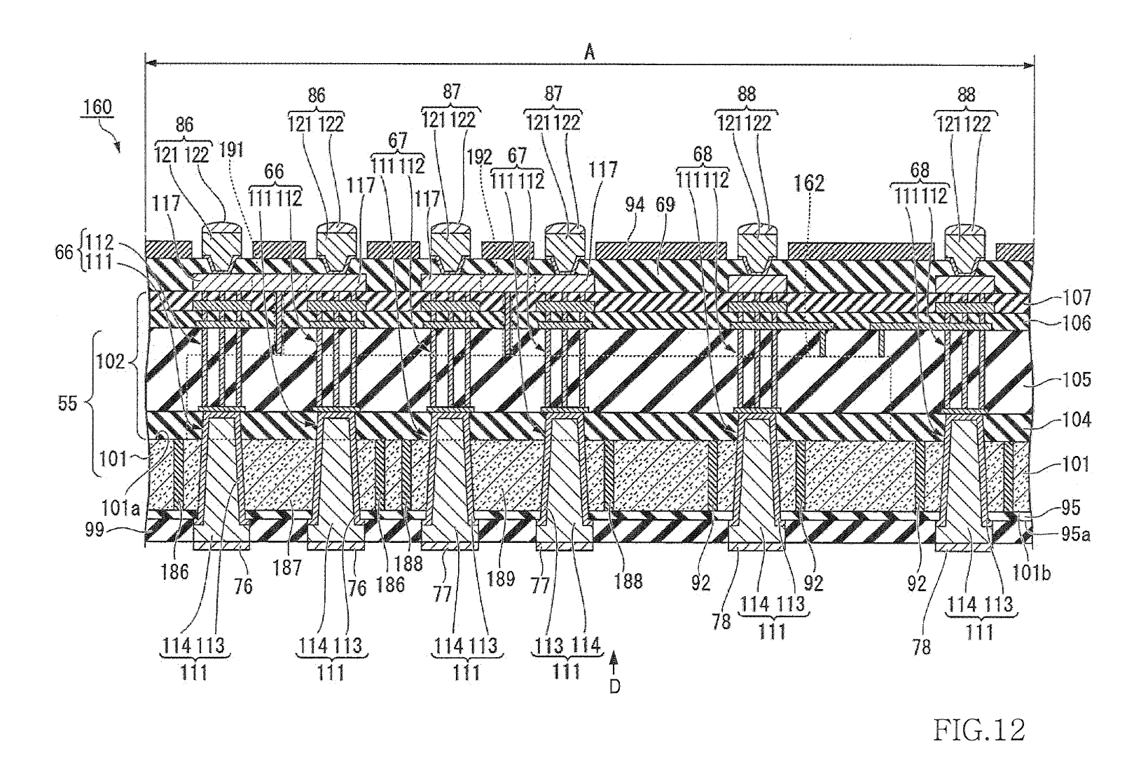

Turning to FIG. 12, the same reference numerals are given to the same constituent elements as those of the structure illustrated in FIGS. 3 and 11.

The following describes a concrete configuration of the semiconductor chip 160 of the third embodiment with reference to FIG. 12.

The semiconductor chip 160 according to the third embodiment has the same configuration as that of the semiconductor chip 13-1 of the first embodiment except that a power supply electrode insulating ring 186, a ground electrode insulating ring 188, the internal circuit 162, and wiring patterns 191 and 192 are provided in place of the insulating ring 92 surrounding the through substrate conductor 111 constituting each of the power supply penetrating electrode 66 and ground penetrating electrode 67, and the storage area section 52.

Further, although not illustrated, the semiconductor chip 160 of the third embodiment has a structure (including the first to fourth penetrating electrodes 61 to 64) formed in the area B of FIG. 1.

The wiring pattern 191 is provided between the plurality of (two, in FIG. 12) power supply penetrating electrodes 66 surrounded by the power supply electrode insulating ring 186. The wiring pattern 191 is connected to the wiring layers 117 provided in the plurality of power supply penetrating electrodes 66 and the internal circuit 162. With this configuration, the wiring pattern 191 electrically connects the plurality of power supply penetrating electrodes 66 and the internal circuit 162.

The wiring pattern 192 is provided between the plurality of (two, in FIG. 12) ground penetrating electrodes 67 surrounded by the ground electrode insulating ring 188. The wiring pattern 192 is connected to the wiring layers 117 provided in the plurality of ground penetrating electrodes 67 and the internal circuit 162. With this configuration, the wiring pattern 192 electrically connects the plurality of ground penetrating electrodes 67 and the internal circuit 162.

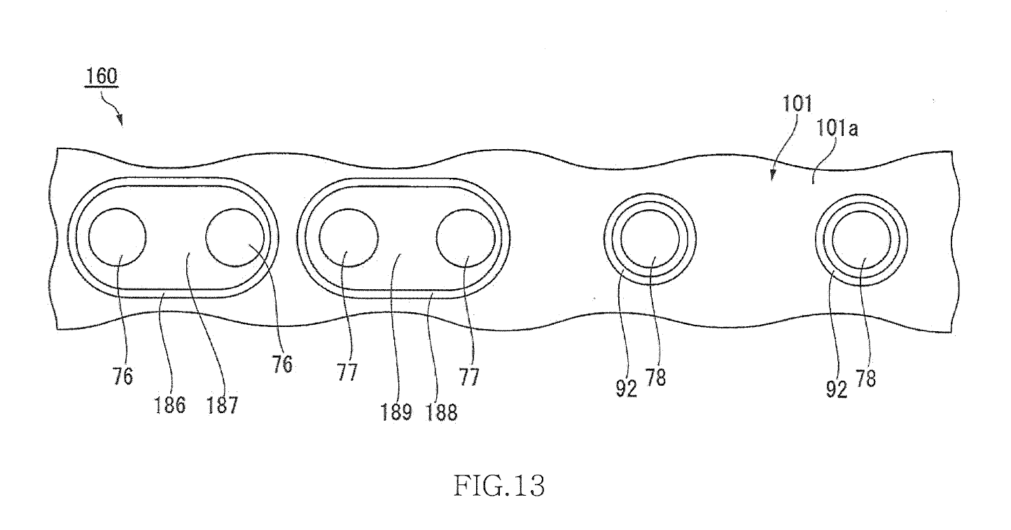

Turning to FIG. 13, the same reference numerals are given to the same constituent elements as those of the semiconductor chip 160 illustrated in FIG. 12.

Referring to FIGS. 12 and 13, the power supply electrode insulating ring 186 is a cylindrical insulator penetrating the semiconductor substrate 101, and is disposed so as to surround the through substrate conductor 111 of the plurality of (two, in FIG. 12) power supply electrodes 66 having the same potential.

With this configuration, a part of the semiconductor substrate 101 that is surrounded by the power supply electrode insulating ring 186 functions as a fourth conductive path 187 that electrically connects the plurality of substrate penetrating electrodes 111 surrounded by the power supply electrode insulating ring 186.

The plurality of power supply penetrating electrodes 66 surrounded by the power supply electrode insulating ring 186 have the same potential, so that no problem occurs even when the plurality of power supply penetrating electrodes 66 are surrounded by one power supply electrode insulating ring 186.

By forming the power supply electrode insulating ring 186 that surrounds the through substrate conductor ill of the plurality of respective power supply penetrating electrodes 66 that penetrate the semiconductor substrate 101 and have the same potential, it is possible to reduce an area occupancy of the power supply electrode insulating ring 186 in the semiconductor substrate 101 as compared to a case where one insulating ring 92 (see FIG. 3) is provided for one substrate penetrating electrode 111 of each of the plurality of the power supply penetrating electrodes 66.

As a result, it is possible to reduce the size of the semiconductor chip 160 in a direction along the front surface 101a of the semiconductor substrate 101.

The ground electrode insulating ring 188 is a cylindrical insulator penetrating the semiconductor substrate 101, and is disposed so as to surround the substrate penetrating electrodes 111 of the plurality of (two, in FIG. 12) respective ground penetrating electrodes 67 having the same potential.

With this configuration, a part of the semiconductor substrate 101 that is surrounded by the ground electrode insulating ring 188 functions as a fifth conductive path 189 that electrically connects the through substrate conductor 111 of the plurality of ground penetrating electrodes 67 surrounded by the ground electrode insulating ring 188.

The plurality of ground penetrating electrodes 67 surrounded by the ground electrode insulating ring 188 have the same potential, so that no problem occurs even when the through substrate conductor 111 of the plurality of ground penetrating electrodes 67 are surrounded by one ground electrode insulating ring 188.

By forming the ground electrode insulating ring 188 that surrounds the through substrate conductor 111 of the plurality of respective ground penetrating electrodes 67 that penetrate the semiconductor substrate 101 and have the same potential, it is possible to reduce an area occupancy of the ground electrode insulating ring 188 in the semiconductor substrate 101 as compared to a case where one insulating ring 92 (see FIG. 3) is provided for one through substrate conductor 111 of each of the plurality of the ground penetrating electrodes 67.

As a result, it is possible to reduce the size of the semiconductor chip 160 in a direction along the front surface 101a of the semiconductor substrate 101.

As described above, the semiconductor chip according to the third embodiment has the plurality of power supply penetrating electrodes 66 penetrating the semiconductor chip body 55 and connected to the internal circuit 162, the plurality of ground penetrating electrodes 67 penetrating the semiconductor chip body 55 and connected to the internal circuit 162, the power supply electrode insulating ring 186 disposed in the semiconductor substrate 101 so as to penetrate therethrough and surround the plurality of power supply penetrating electrodes 66, and the ground electrode insulating ring 188 disposed in the semiconductor substrate 101 so as to penetrate therethrough and surround the plurality of ground penetrating electrodes 67. With this configuration, it is possible to reduce an area occupancy of the power supply electrode insulating ring 186 in the semiconductor substrate 101 and that of the ground electrode insulating ring 188 in the semiconductor substrate 101 as compared to a case where one insulating ring 92 (see FIG. 3) is provided for one through substrate conductor 111 of each of the plurality of power supply penetrating electrodes 66 and one through substrate conductor 111 of each of the plurality of ground penetrating electrodes 67.

As a result, it is possible to reduce the size of the semiconductor chip 160 in a direction along the front surface 101a of the semiconductor substrate 101.

Although the power supply electrode insulating ring 186 surrounds the through substrate conductor 111 of the two respective power supply penetrating electrodes 66 and the ground electrode insulating ring 188 surrounds the through substrate conductor 111 of the two respective ground penetrating electrodes 67 in the third embodiment, the power supply electrode insulating ring 186 may be formed to surround the through substrate conductor 111 of three or more respective power supply penetrating electrodes 66 and the ground electrode insulating ring 188 may be formed to surround the through substrate conductor 111 of three or more respective ground penetrating electrodes 67.

Although the wide-IO DRAM which is a memory semiconductor chips is exemplified as the semiconductor chip 160 in the third embodiment, the type of the semiconductor chip 160 is not limited to this but the present invention may be applied to any type of the semiconductor chip as long as it has the first to fourth penetrating electrodes 61 to 64.

Further, the stacked-type semiconductor device may be formed by stacking the two semiconductor chips 160 in place of the semiconductor chips 13-1 and 13-2 illustrated in FIG. 1.

It is apparent that the present invention is not limited to the above embodiments, but may be modified and changed without departing from the scope and spirit of the invention.

For example, the power supply electrode insulating ring 186 and ground electrode insulating ring 188 described in the third embodiment may be applied to the semiconductor chips 13-1 and 13-2 of the first embodiment and the semiconductor chip 145 of the second embodiment.

The present invention can be applied to a semiconductor chip, a measurement method of a resistance thereof, and a semiconductor device.

What is claimed is:

1. A semiconductor chip comprising:
a semiconductor chip body including a semiconductor substrate and a circuit element layer provided on a main surface of the semiconductor substrate, the circuit element layer including a plurality of circuit elements;
first to fourth penetrating electrodes penetrating the semiconductor chip body;
a first conductive path electrically connected between the first penetrating electrode and the second penetrating electrode without being in contact with any one of the circuit elements;
a second conductive path electrically connected between the first penetrating electrode and the third penetrating electrode without being in contact with any one of the circuit elements; and
a third conductive path electrically connected between the second penetrating electrode and the fourth penetrating electrode without being in contact with any one of the circuit elements.

2. The semiconductor chip as claimed in claim 1, further comprising first to fourth insulating rings provided to penetrate the semiconductor substrate, wherein
the first to fourth insulating rings surround the first to fourth penetrating electrodes, respectively,
the first conductive path comprises a first conductive pattern electrically connected between the first and second penetrating electrodes,
the second conductive path comprises a second conductive pattern electrically connected between the first and third penetrating electrodes, and
the third conductive path comprises a third conductive pattern electrically connected between the second and fourth penetrating electrodes.

3. The semiconductor chip as claimed in claim 1, further comprising:
a first insulating ring provided to penetrate the semiconductor substrate and surrounding a part of the first penetrating electrode and a part of the third penetrating electrode; and
a second insulating ring provided to penetrate the semiconductor substrate and surrounding a part of the second penetrating electrode and a part of fourth penetrating electrode, wherein
the first conductive path comprises a conductive pattern electrically connected between the first and second penetrating electrodes,
the second conductive path comprises a part of the semiconductor substrate surrounded by the first insulating ring, and
the third conductive path comprises another part of the semiconductor substrate surrounded by the second insulating ring.

4. The semiconductor chip as claimed in claim 1, wherein the first to fourth penetrating electrodes function as dummy electrodes for measurement of a resistance value.

5. The semiconductor chip as claimed in claim 2, wherein
each of the first to fourth penetrating electrodes includes a through substrate conductor that fills a through hole penetrating the semiconductor substrate and a multilayer wiring section that is disposed to penetrate the circuit element layer and connected to the through substrate conductor, and
the first conductive pattern is provided on the circuit element layer and connected between the multilayer wiring section of the first penetrating electrode and that of the second penetrating electrode.

6. The semiconductor chip as claimed in claim 5, wherein
the through substrate conductor includes a seed layer that covers an inner wall of the through hole and a conductive film that fills the through hole with intervention of the seed layer,
the seed layer of the first penetrating electrode and the seed layer of the third penetrating electrode are continuously provided to function as the second conductive pattern, and
the seed layer of the second penetrating electrode and the seed layer of the fourth penetrating electrode are continuously provided to function as the third conductive pattern.

7. The semiconductor chip as claimed in claim 3, wherein
each of the first to fourth penetrating electrodes includes a through substrate conductor that fills a through hole penetrating the semiconductor substrate and a multilayer wiring section that is disposed to penetrate the circuit element layer and connected to the through substrate conductor, and
the conductive pattern is provided on the circuit element layer and connected between the multilayer wiring section of the first penetrating electrode and that of the second penetrating electrode.

8. The semiconductor chip as claimed in claim 1, wherein each of the first to fourth penetrating electrodes includes a first bump electrode exposed from a back surface of the semiconductor substrate that is opposite to the main surface thereof.

9. The semiconductor chip as claimed in claim 1, wherein each of the first to fourth penetrating electrodes includes a second bump electrode exposed from the circuit element layer.

10. The semiconductor chip as claimed in claim 1, further comprising:
a plurality of fifth penetrating electrodes that penetrate the semiconductor chip body and are connected to a first power node of at least one of the circuit elements;
a plurality of sixth penetrating electrodes that penetrate the semiconductor chip body and are connected to a second power node of at least one of the circuit elements;
a plurality of fifth insulating rings that are disposed in the semiconductor substrate to penetrate therethrough and surround a part of the fifth penetrating electrodes, respectively; and
a plurality of sixth insulating rings that are disposed in the semiconductor substrate to penetrate therethrough and surround a part of the sixth penetrating electrodes, respectively.

11. The semiconductor chip as claimed in claim 10, wherein each of the fifth penetrating electrodes includes a third bump electrode exposed from a back surface of the semiconductor substrate that is opposite to the main surface thereof.

12. The semiconductor chip as claimed in claim 10, wherein each of the sixth penetrating electrodes includes a fourth bump electrode exposed from the circuit element layer.

13. A method of measuring resistance of a semiconductor chip, the method comprising:
forming a plurality of circuit elements and first to fourth penetrating electrodes that penetrating the semiconductor chip; and
measuring a voltage between the third and fourth penetrating electrodes while supplying current from the first penetrating electrode to the second penetrating electrode without passing through any one of the circuit elements.

14. The resistance measurement method as claimed in claim 13, wherein the measuring is performed by connecting first to fourth probe electrodes to the first to fourth penetrating electrodes, respectively.

15. A semiconductor device comprising:
a semiconductor substrate;
a plurality of circuit elements formed on the semiconductor substrate;
first and second penetrating electrodes each penetrating the semiconductor substrate;
a first conductive path passing current from the first penetrating electrode to second penetrating electrode without passing through any of the circuit elements;
a third penetrating electrode penetrating the semiconductor substrate and configured to have substantially the same potential as that of the first penetrating electrode; and
a fourth penetrating electrode penetrating the semiconductor substrate and configured to have substantially the same potential as that of the second penetrating electrode.

16. The semiconductor device as claimed in claim 15, further comprising:
a second conductive path that makes the first and third penetrating electrodes conductive substantially without carrying current; and
a third conductive path that makes the second and fourth penetrating electrodes conductive substantially without carrying current.

17. The semiconductor device as claimed in claim 16, wherein the semiconductor substrate includes a first part being between the first and third penetrating electrodes and functioning as the second conductive path, and a second part being between the second and fourth penetrating electrodes and serving as the third conductive path.

18. The semiconductor device as claimed in claim 15, further comprising:
a first insulating ring that surrounds a part of the first penetrating electrode and a part of third penetrating electrode; and
a second insulating ring that surrounds a part of the second penetrating electrode and a part of fourth penetrating electrode.
